(19) United States
(12) Patent Application Publication
(10) Pub. No.: US 2010/0058585 A1
(43) Pub. Date: Mar. 11, 2010

(54) METHOD OF MANUFACTURING PRINTED CIRCUIT BOARD

(75) Inventors: Sergey Remizov, Suwon-si (KR); Jae-Woo Joung, Suwon-si (KR); Hyun-Chul Jung, Yongin-si (KR); Young-Ah Song, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/429,511

(22) Filed: Apr. 24, 2009

(30) Foreign Application Priority Data
Sep. 8, 2008 (KR) 10-2008-0088414

(51) Int. Cl. H05K 3/10

(52) U.S. Cl. 29/846

(57) ABSTRACT

A method of manufacturing a printed circuit board is disclosed. The method of manufacturing a printed circuit board in accordance with an embodiment of the present invention can include: forming a circuit pattern by discharging conductive ink on a carrier through inkjet printing, heating and sintering the circuit pattern, and transferring the circuit pattern on an insulation layer by stacking the carrier on the insulation layer such that the circuit pattern is buried in the insulation layer. In accordance with an embodiment of the present invention, a minute, precise circuit pattern can be formed through inkjet printing, and adhesion between the circuit pattern and the insulation layer can be improved.

### CROSS-REFERENCE TO RELATED APPLICATIONS

This application claims the benefit of Korean Patent Application No. 10-2008-0088414, filed with the Korean Intellectual Property Office on Sep. 8, 2008, the disclosure of which is incorporated herein by reference in its entirety.

### BACKGROUND

1. Technical Field

The present invention relates to a method of manufacturing a printed circuit board.

2. Description of the Related Art

Recent years have seen the development of an inkjet printing method that can be applied to form conductive patterns for printed circuit boards, organic thin film transistors (OTFT), radio frequency identification (RFID), micro-electromechanical (MEMS) and other electronic products.

However, when forming a conductive pattern on an insulation layer through the conventional inkjet printing method, a minute metal pattern may be formed, but it is difficult to provide adequate adhesion between the insulation layer and the conductive pattern.

In the conventional inkjet printing method, conductive ink is discharged on the insulation layer and then dried and sintered to form the conductive pattern of grains, in which nano-particles of the conductive ink are joined together.

In this conventional technology, however, the conductive pattern, which is composed of grains, is in point-contact with the insulation layer, thereby significantly losing the tightness of adhesion between the conductive pattern and the insulation layer.

### SUMMARY

The present invention provides a method of manufacturing a printed circuit board that can form a minute, precise circuit pattern through inkjet printing and improve adhesion between the circuit pattern and an insulation layer.

An aspect of the invention provides a method of manufacturing a printed circuit board. The method of manufacturing a printed circuit board in accordance with an embodiment of the present invention can include: forming a circuit pattern by discharging conductive ink on a carrier through inkjet printing; heating and sintering the circuit pattern; and transferring the circuit pattern on an insulation layer by stacking the carrier on the insulation layer such that the circuit pattern is buried in the insulation layer.

In this case, the method further can include, before the forming of the circuit pattern, surface treating the carrier such that a surface of the carrier becomes hydrophobic.

The surface treating of the carrier can include plasma treating the surface of the carrier.

The surface treating of the carrier can include forming a hydrophobic substance layer on the carrier.

Here, the hydrophobic substance layer can be made of a material comprising fluoro-resin.

The carrier can be made of a material comprising a hydrophobic substance.

Here, the carrier can be made of a material comprising fluoro-resin.

The method can further include, between the sintering of the circuit pattern and the transferring of the circuit pattern, surface treating the circuit pattern such that adhesive strength between the circuit pattern and the insulation layer is increased.

In this case, the surface treating of the circuit pattern can include performing a roughening treatment on a surface of the circuit pattern.

In addition, the method can further include, between the sintering of the circuit pattern and the transferring of the circuit pattern, forming an adhesive layer on the circuit pattern such that the adhesive strength between the circuit pattern and the insulation layer is increased.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a printed circuit board in accordance with an embodiment of the present invention.

FIGS. 2 to 8 are cross sectional views illustrating each respective manufacturing process of a printed circuit board in accordance with an embodiment of the present invention.

### DETAILED DESCRIPTION

A method of manufacturing a printed circuit board in accordance with certain embodiments of the invention will be described below in more detail with reference to the accompanying drawings. Those components that are the same or are in correspondence are rendered the same reference numeral regardless of the figure number, and redundant explanations are omitted.

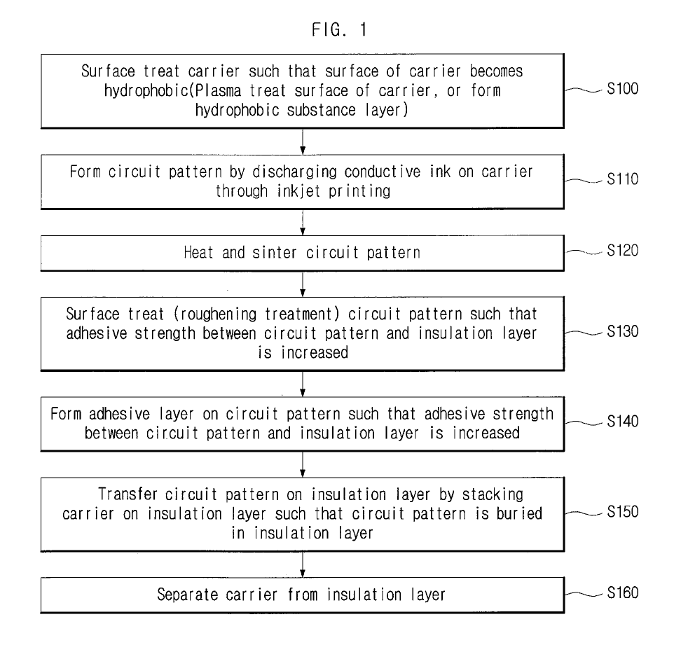

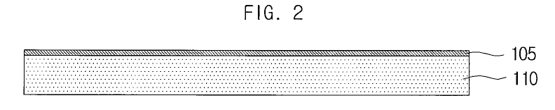

FIG. 1 is a flowchart illustrating a method of manufacturing a printed circuit board 100 in accordance with an embodiment of the present invention. FIGS. 2 to 8 are cross sectional views illustrating each respective manufacturing process of the printed circuit board 100 in accordance with an embodiment of the present invention.

The method of manufacturing the printed circuit board 100 in accordance with an embodiment of the present embodiment includes forming a circuit pattern 140 by discharging conductive ink 130 on a carrier 110 through inkjet printing, heating and sintering the circuit pattern 140, and transferring the circuit pattern 140″ on an insulation layer 160 by stacking the insulation layer 160 on the carrier 110 such that the circuit pattern 140″ is buried in the insulation layer 160.

In the present embodiment described above, the circuit patterns 140 and 140′ can be formed finely and precisely by way of inkjet printing, and adhesion between the circuit pattern 140″ and the insulation layer 160 can be improved by transferring the circuit pattern 140″ on the insulation layer 160 through the use of the carrier 110.

Below, each manufacturing process will be described in more detail by referring to FIGS. 1 to 8.

First, as described in FIG. 2, a surface of the carrier 110 is treated such that the carrier 110 has a hydrophobic surface (S 100). Here, the carrier 110 can be rigid enough to avoid a damage by heat or pressure when sintering the circuit pattern 140 or transferring the circuit pattern 140″ and to have the circuit patterns 140, 140′ and 140″ avoid a damage by the deformation of the carrier 110 caused by external stimulation. The carrier 110 may have a coefficient of thermal expansion corresponding to the circuit patterns 140, 140′ and 140″.

A surface treating process in the present process can be performed by either plasma treating a surface of the carrier 110 or forming a hydrophobic substance layer 105 on the carrier 110. Below, each process will be described.

Plasma treatment is a surface treatment process that treats the surface of the carrier 110 with fluorine plasma such that the surface of the carrier 110 becomes hydrophobic. That is, for example, fluorocarbon, such as CF₄, C₂F₆ and CF₃H, is injected into a chamber, in which the carrier is positioned, and then pressure is applied, discharging electricity.

The formation of a hydrophobic substance layer 105 is a process that forms a film made of fluoro-resin, for example, polytetrafluoroethylene (PTFE), perfluoroalkoxy (PFA), fluorinated ethylenepropylene (FEP) or a combination of at least two of the above.

Here, the hydrophobic substance layer can be formed by directly stacking a film or coating liquid-phase resin through various known ways, such as spraying, dipping, spin coating, screen printing or inkjet printing.

As such, by surface treating the carrier 110 to be hydrophobic, the conductive ink 130 being discharged by way of inkjet printing can be prevented from being spread on the carrier 110 and can form the fine circuit pattern 140. At the same time, the carrier 110 can be easily separated from the insulation layer 160 after transferring the circuit pattern 140″ in the insulation layer 160.

On the other hand, the carrier 110 itself can be made of a hydrophobic substance that is made of the fluoro-resin described above.

As the carrier 110 itself is made of a hydrophobic substance described above, the surface of the carrier 110 can be hydrophobic without a further surface treatment process, saving the manufacturing time and cost.

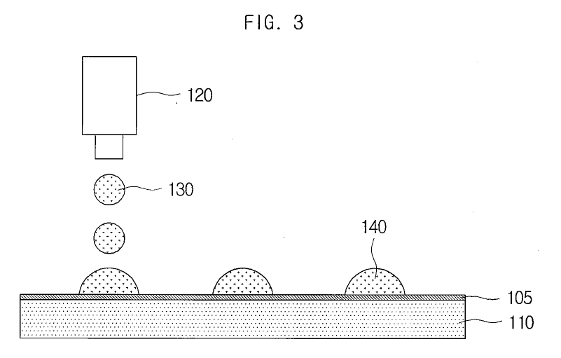

Next, as illustrated in FIG. 3, the circuit pattern 140 is formed on the carrier 110 by discharging the conductive ink 130 from an inkjet head 120 through inkjet printing (S110). That is, as described above, since the surface of the carrier 110 becomes hydrophobic, an liquid-droplet of the circuit pattern 140 can be concentrated without being spread when forming the circuit pattern 140 by discharging the conductive ink 130 on the carrier 110 through inkjet printing, thereby implementing the circuit pattern 140 more finely and precisely. Below, an example of forming the fine pattern will be described.

In case the carrier 110 is made of bismaleimide triazine resin and the size of the conductive ink 130 is 30 micrometers, a contact angle formed between the carrier 110 and the circuit pattern 140 becomes close to 0 degrees and the width of the circuit pattern 140 becomes 110 micrometers before the surface treating.

However, after surface treating the carrier 110 by using the CF₄ plasma described above, the contact angle formed between the carrier 110 and the circuit pattern 140 becomes 45 degrees and the width of the circuit pattern 140 will be reduced to 42 micrometers.

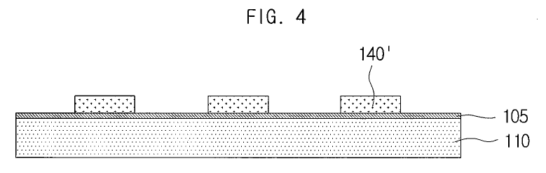

Next, the circuit pattern 140 is heated and sintered, as illustrated in FIG. 4 (S120). As such, by heating the circuit pattern 140, the nano-particles of the conductive ink 130 can be joined with one another, forming a hardened circuit pattern 140′. In this case, gas can be injected or pressure can be applied to prevent the circuit patterns 140 and 140′ from oxidation.

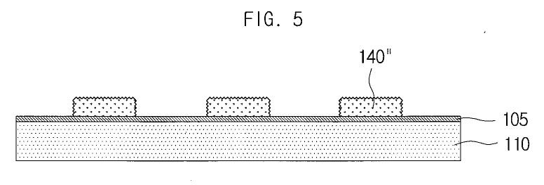

Next, the circuit pattern 140′ is surface treated such that the adhesive strength between the circuit pattern 140′ and the insulation layer 160 is increased, as described in FIG. 5 (S130). As a process to increase the adhesive strength between the circuit pattern 140′ and the insulation layer 160 in order to transfer the circuit pattern 140′ into the insulation layer 160, the surface of the circuit pattern 140′ is treated such that the surface roughness of the circuit pattern 140′ is increased. The roughening treatment can be performed by various methods, such as etching the circuit pattern 140′ or oxidizing the circuit pattern 140′ through brown oxide or black oxide.

By roughening the surface of the circuit pattern 140′ described above, the surface area of the circuit pattern 140′ can be increased. Thus, when transferring the circuit pattern 140″ into the insulation layer 160, the circuit pattern 140″ and the insulation layer 160 can be strongly coupled to each other due to the increased surface area formed between the circuit pattern 140″ and the insulation layer 160.

After the roughening treatment disclosed in the present embodiment, the surface treatment can be performed in various ways. For instance, the adhesive strength between the circuit pattern 140″ and the insulation layer 160 can be further improved through a silane treatment.

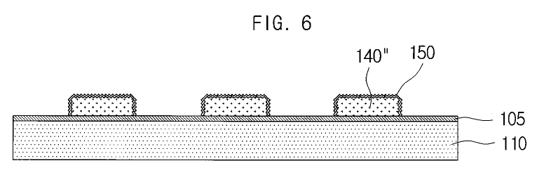

Next, an adhesive layer 150 is formed on the circuit pattern 140″ such that the adhesive strength between the circuit pattern 140″ and the insulation layer 160 is increased, as illustrated in FIG. 6 (S140). After roughening the surface of the circuit pattern 140″, the adhesive layer 150 can be formed on the circuit pattern 140″ in order to further improve the adhesive strength between the circuit pattern 140″ and the insulation layer 160.

The adhesive layer 150, like the hydrophobic substance layer 105 described above, can be formed by stacking a film or coating liquid-phase adhesive resin through various known ways, such as spraying, dipping, spin coating, screen printing or inkjet printing.

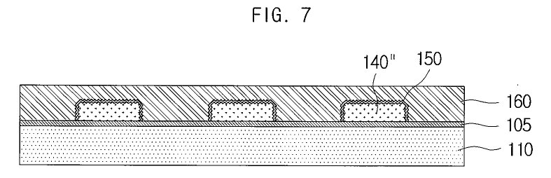

Next, the circuit pattern 140″ is transferred onto the insulation layer 160 by stacking the carrier 110 on the insulation layer 160 such that the circuit pattern 140″ is buried in the insulation layer 160, as illustrated in FIG. 7 (S150). That is, after stacking the carrier 110 having the circuit pattern 140″ formed thereon on the half-hardened insulation layer 160, for example, prepreg, the insulation layer 160 and the carrier 110 can be compressed together by using, for example, a press. At the same time, the circuit pattern 140″ can be buried in the insulation layer 160 by heating and hardening the insulation layer 160, and thus the circuit pattern 140″ can be transferred on the insulation layer 160.

As such, the strength of adhesion between the circuit pattern 140″ and the insulation layer 160 can be significantly improved by increasing the contact area of the circuit pattern 140″ and the insulation layer 160, in which the circuit pattern 140″ is buried in the insulation layer 160.

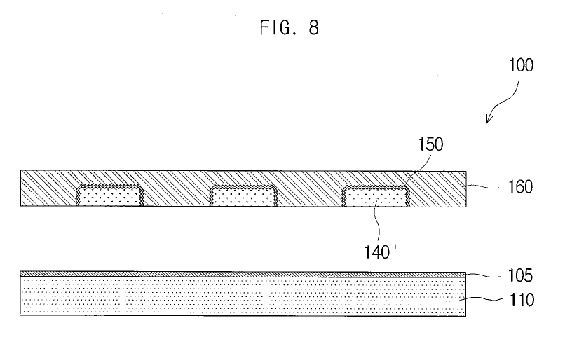

Next, the carrier 110 is separated from the insulation layer 160, as illustrated in FIG. 8 (S160). As described above, while the carrier 110 is weakly adhered to the circuit pattern 140″ and the insulation layer 160 since the carrier 110 has a hydrophobic surface, the circuit pattern 140″ and the insulation layer 160 are strongly adhered to each other because the circuit pattern 140″ is roughened, has the adhesive layer 150 formed thereon and is buried in the insulation layer 160. Therefore, the carrier 110 can be easily separated from the insulation layer 160, without the circuit pattern 140″.

As such, the printed circuit board 100 in which the circuit pattern 140″ is buried in the insulation layer 160 can be implemented.

In accordance with the method of manufacturing the printed circuit board 100 based on the present embodiment, the adhesive strength between the circuit pattern 140″ and the insulation layer 160 can be significantly improved by increasing the contact area of the circuit pattern 140″ and the insulation layer 160, in which the circuit pattern 140″ is buried, as well as by roughening a surface of the circuit pattern 140′ and by forming the adhesive layer 150 on the circuit pattern 140″.

Below, the present embodiment will be further described with an actual test examples.

### TEST EXAMPLE 1

The curing and sintering processes are performed by forming the circuit pattern 140 through inkjet printing on the carrier 110 made of polytetrafluoroethylene (PTFE) and injecting atmosphere gas at the temperature of 200 degrees Celsius. Then, the carrier 110 is compressed to the insulation layer 160 made of bismaleimide triazine resin with the pressure of 5 MPa. After the insulation layer 160 is heated and hardened at the temperature of 190 degrees Celsius, the carrier 110 is separated from the insulation layer 160.

### TEST EXAMPLE 2

After coating the hydrophobic substance layer 105 made of fluoro-resin on the carrier 110 made of polyimide, the curing and sintering processes are performed by forming the circuit pattern 140 through inkjet printing on the carrier 110 and injecting atmosphere gas at the temperature of 200 degrees Celsius. Then, the carrier 110 is compressed to the insulation layer 160 made of bismaleimide triazine resin with the pressure of 2 MPa. After the insulation layer 160 is heated and hardened at the temperature of 190 degrees Celsius, the carrier 110 is separated from the insulation layer 160.

By forming the hydrophobic substance layer 105 made of fluoro-resin on the carrier 110, as described above, the carrier 110 and the insulation layer 160 can be easily separated from each other.

### TEST EXAMPLE 3

The curing and sintering processes are performed by forming the circuit pattern 140 through inkjet printing on the carrier 110 made of bismaleimide triazine resin and injecting atmosphere gas at the temperature of 200 degrees Celsius. Then, the 10 micrometer-thick adhesive layer 150 made of polyimide is stacked on the circuit pattern 140′, and the carrier 110 is compressed with the pressure of 2 MPa to the insulation layer 160 made of bismaleimide triazine resin. After the insulation layer 160 is heated and hardened at the temperature of 190 degrees Celsius, the carrier 110 is separated from the insulation layer 160.

The results of testing the strength of adhesion between the circuit pattern 140′ and the insulation layer 160 of the printed circuit board 100 show that the adhesive strength is increased up to 0.85 N/mm when the adhesive layer 150 is used, from 0.05 N/mm when the adhesive layer 150 is not used.

According to the embodiments of the present invention as set forth above, the circuit pattern can be finely and precisely formed through inkjet printing, and the adhesive strength between the circuit pattern and the insulation layer can be improved.

While the spirit of the invention has been described in detail with reference to a certain embodiment, the embodiment is for illustrative purposes only and shall not limit the invention. It is to be appreciated that those skilled in the art can change or modify the embodiment without departing from the scope and spirit of the invention. As such, many embodiments other than that set forth above can be found in the appended claims.

What is claimed is:

1. A method of manufacturing a printed circuit board, the method comprising:
forming a circuit pattern by discharging conductive ink on a carrier through inkjet printing;
heating and sintering the circuit pattern; and
transferring the circuit pattern on an insulation layer by stacking the carrier on the insulation layer such that the circuit pattern is buried in the insulation layer.

2. The method of claim 1, further comprising, before the forming of the circuit pattern, surface treating the carrier such that a surface of the carrier becomes hydrophobic.

3. The method of claim 2, wherein the surface treating of the carrier comprises plasma treating the surface of the carrier.

4. The method of claim 2, wherein the surface treating of the carrier comprises forming a hydrophobic substance layer on the carrier.

5. The method of claim 4, wherein the hydrophobic substance layer is made of a material comprising fluoro-resin.

6. The method of claim 1, wherein the carrier is made of a material comprising a hydrophobic substance.

7. The method of claim 6, wherein the carrier is made of a material comprising fluoro-resin.

8. The method of claim 1, further comprising, between the sintering of the circuit pattern and the transferring of the circuit pattern, surface treating the circuit pattern such that adhesive strength between the circuit pattern and the insulation layer is increased.

9. The method of claim 8, wherein the surface treating of the circuit pattern comprises performing a roughening treatment on a surface of the circuit pattern.

10. The method of claim 9, further comprising, between the sintering of the circuit pattern and the transferring of the circuit pattern, forming an adhesive layer on the circuit pattern such that the adhesive strength between the circuit pattern and the insulation layer is increased.
